(19) United States
(12) Patent Application Publication
(10) Pub. No.: US 2025/0248271 A1
(43) Pub. Date: Jul. 31, 2025

(54) DISPLAY PANEL AND DISPLAY APPARATUS

(71) Applicants: Hefei Visionox Technology Co., Ltd., Hefei (CN); Visionox Technology Inc., Suzhou (CN)

(72) Inventors: Xuejing ZHU, Hefei (CN); Yuan YAO, Hefei (CN); Xiaoxi SUN, Hefei (CN); Bo RAO, Hefei (CN); Qing BAI, Hefei (CN); Shizhen FENG, Hefei (CN)

(73) Assignees: Hefei Visionox Technology Co., Ltd., Hefei (CN); Visionox Technology Inc., Suzhou (CN)

(21) Appl. No.: 18/744,802

(22) Filed: Jun. 17, 2024

(30) Foreign Application Priority Data
Jan. 31, 2024 (CN) 202410141739.8

(51) Int. Cl. H10K 59/80; H10K 59/122

(52) U.S. Cl. CPC H10K 59/873; H10K 59/122

(57) ABSTRACT

A display panel and a display apparatus, the display panel includes a display region and a non-display region surrounding at least a part of the display region, and the display panel includes: a base plate; a pixel definition layer provided on the base plate the pixel definition layer includes a pixel definition portion located in the display region and a definition portion located in the non-display region, and the pixel definition portion is provided with a plurality of pixel openings; a light-emitting layer including light-emitting units each located in the pixel opening; and an encapsulation layer located on a side of the light-emitting layer away from the base plate. The encapsulation layer includes a first encapsulation layer and a second encapsulation layer located on a side of the first encapsulation layer away from the light-emitting layer.

### CROSS REFERENCE TO RELATED APPLICATION

The present application claims priority to Chinese Patent Application No. 202410141739.8 filed on Jan. 31, 2024, and titled “DISPLAY PANEL AND DISPLAY APPARATUS”, which is incorporated herein by reference in its entirety.

### TECHNICAL FIELD

The present application relates to the technical field of display devices, and particularly to a display panel and a display apparatus.

### BACKGROUND

Organic Light-Emitting Diode (OLED) displays are also known as organic electroluminescent displays. Compared to the existing liquid crystal displays, OLED displays have a set of advantages such as self-luminescence, wide viewing angle, ultra-lightness, ultra-thinness, high brightness, low power consumption and fast response, and the response speed of the OLED displays can be 1000 times of that of the liquid crystal displays. Accordingly, OLED displays have become very popular flat panel display products at home and abroad, and have a broad application prospect.

However, the process performance of the display panels needs to be improved.

### SUMMARY

Embodiments of the present application provide a display panel and a display apparatus, which is intended to improve the process performance of the display panel.

Embodiments of a first aspect of the present application provide a display panel including a display region and a non-display region surrounding at least a part of the display region, and the display panel includes: a base plate; a pixel definition layer provided on the base plate, wherein the pixel definition layer includes a pixel definition portion located in the display region and a definition portion located in the non-display region, and the pixel definition portion is provided with a plurality of pixel openings; a light-emitting layer including light-emitting units each located in the pixel opening; and an encapsulation layer located on a side of the light-emitting layer away from the base plate, wherein the encapsulation layer includes a first encapsulation layer and a second encapsulation layer located on a side of the first encapsulation layer away from the light-emitting layer, the first encapsulation layer is located in the display region and includes an encapsulation portion encapsulates the light-emitting units, and at least a part of the second encapsulation layer extends to the non-display region and is connected to the definition portion.

The embodiments of a first aspect of the present application further provide a display panel including a display region and a non-display region surrounding at least a part of the display region, and the display panel includes: a base plate; a light-emitting layer including a plurality of light-emitting units; and an encapsulation layer located on a side of the light-emitting layer away from the base plate, wherein the encapsulation layer includes a first encapsulation layer and a second encapsulation layer located on a side of the first encapsulation layer away from the light-emitting layer, the first encapsulation layer is located in the display region and includes a plurality of encapsulation portions respectively covering the plurality of light-emitting units, and the second encapsulation layer covers the plurality of encapsulation portions.

Embodiments of a second aspect of the present application provide a display apparatus including the display panel according to any of the embodiments of the first aspect.

In the display panel according to the embodiments of the present application, the display panel includes the base plate, the pixel definition layer, the light-emitting layer, and the encapsulation layer. The pixel definition layer includes the pixel definition portion located in the display region and the definition portion located in the non-display region. The pixel definition portion in the display region is provided with the pixel openings, and the light-emitting unit is provided within the pixel opening, so that the display region of the display panel can emit light and display. The encapsulation layer includes the first encapsulation layer and the second encapsulation layer, and the encapsulation portion of the first encapsulation layer is configured to encapsulate the light-emitting units, so as to reduce the impact of water and oxygen intrusion on the light-emitting effect of the light-emitting units. The second encapsulation layer in the non-display region is connected to the definition portion of the pixel definition layer. That is, the definition portion and the second encapsulation layer extend out from the first encapsulation layer and are connected to each other outside the first encapsulation layer, which can reduce the problem that the encapsulation performance of the second encapsulation layer is affected by the excessive fluidity of the second encapsulation layer caused by the contact area between the first encapsulation layer and the second encapsulation layer being too large. Accordingly, the embodiments of the present application can improve the encapsulation performance of the encapsulation layer, thereby improving the overall process performance of the display panel.

### BRIEF DESCRIPTION OF THE DRAWINGS

Other features, objects and advantages of the present application will become more apparent from reading the following detailed description of the non-limiting embodiments with reference to the accompanying drawings, in which the same or similar reference numerals represent the same or similar features.

FIG. 1 is a schematic structural view of a display panel according to an embodiment of the present application;

FIG. 2 is a cross-sectional view at A-A in FIG. 1;

FIG. 3 is a partial enlarged schematic structural view of FIG. 2;

FIG. 4 is a cross-sectional view at A-A in FIG. 1 in another example;

FIG. 5 is a schematic structural view of a display panel according to another embodiment of the present application

### REFERENCE NUMBER

100: Base plate; 110: Dam; 111: Organic layer; 120: Signal line; 121: Second hole;
130: Pad layer; 140: Planarization layer;
200: Pixel definition layer; 210: Pixel definition portion; 220: Definition portion; 230: Pixel opening; 240: First hole;
300: Light-emitting layer; 310: Light-emitting unit;
400: Encapsulation layer; 410: First encapsulation layer; 411: Encapsulation portion; 420: Second encapsulation layer; 430: Third encapsulation layer;
500: Isolation structure; 510: Isolation opening; 520: First layer; 530: Second layer; 540: Third layer;
700: First electrode layer; 710: First electrode;
800: Second electrode layer; 810: Second electrode;
AA: Display region; NA: Non-display region.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely intended to provide a better understanding of the present application by illustrating examples of the present application. In the accompanying drawings and the following description, at least some of well-known structures and techniques are not shown so as to avoid unnecessary obscurity of the present application. In addition, size of some structures may be exaggerated for clarity. Furthermore, the features, structures, or characteristics described below may be combined in one or more embodiments by any suitable manner.

In the description of the present application, it should be noted that, unless otherwise specified, the term “a plurality of” indicates two or more; the terms “upper”, “lower”, “left”, “right”, “inner”, “outer”, and the like indicate orientations or positional relationships for facilitating and simplifying description of the present application, and do not indicate or imply that the involved devices or elements must have such a particular orientation, or must be constructed and operated in such a particular orientation, and thus should not be construed to limit the present application. In addition, the terms “first”, “second”, and the like are merely used for the purpose of description and should not be interpreted to indicate or imply relative importance.

The directional words appearing in the following description indicate directions shown in the drawings and do not limit the specific structure in the embodiments of the present application. In the description of the present application, it should be further noted that, unless otherwise clearly specified and limited, the terms “installation” and “connection” should be understood in a broad sense, for example, the “connection” may refer to a fixed, a detachable or an integrated connection; and it may refer to a director an indirect connection. For a person skilled in the art, the specific meaning of the terms mentioned above in the present application may be understood in accordance with specific situations.

In the display panel, the display panel includes the light-emitting units and the encapsulation layer configured to encapsulate the light-emitting units. The encapsulation layer typically includes a first inorganic encapsulation layer, an organic encapsulation layer, and a second inorganic encapsulation layer, the organic encapsulation layer typically needs to be located within a region enclosed and formed by the dam of the display panel. In the related art, there is a condition in which the organic encapsulation layer overflows out of a part of the dam.

Reference can be made to applications of PCT/CN2023/134518, 202311499823.9, 202310707209.0, 202311346196.5, 202310692671.8, and 202311091555.7 for the related contents of the isolation structure and the encapsulation layer.

The applicants have found that, since the material of the first inorganic encapsulation layer typically is SiOx, and the main component of the organic encapsulation layer is an organic small molecule, the O bond in the SiOx may bridge with the valence bond in the organic encapsulation layer, thereby increasing the fluidity of the organic encapsulation layer. The organic encapsulation layer crosses the innermost dam easily and overflows between the innermost dam and the outermost dam, thereby reducing the encapsulation length and reducing the yield of the encapsulation layer.

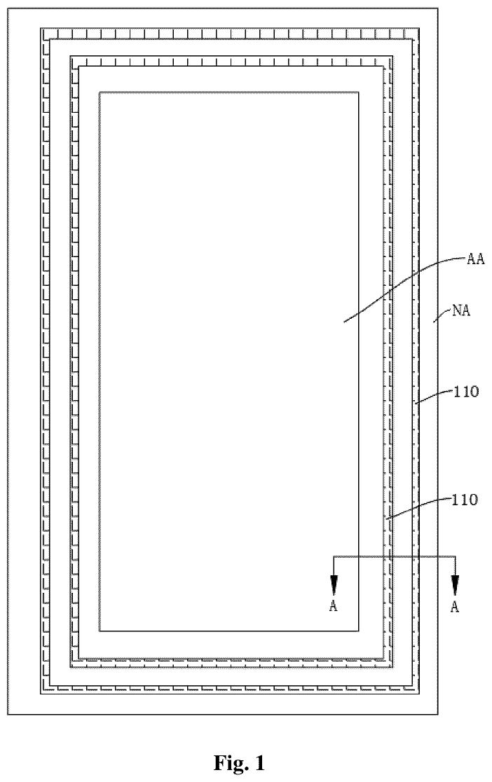

The present application is set forth to reduce the above technical problem. For a better understanding of the present application, the display panel and the display apparatus according to the embodiments of the present application will be described in detail below with reference to FIG. 1 to FIG. 5.

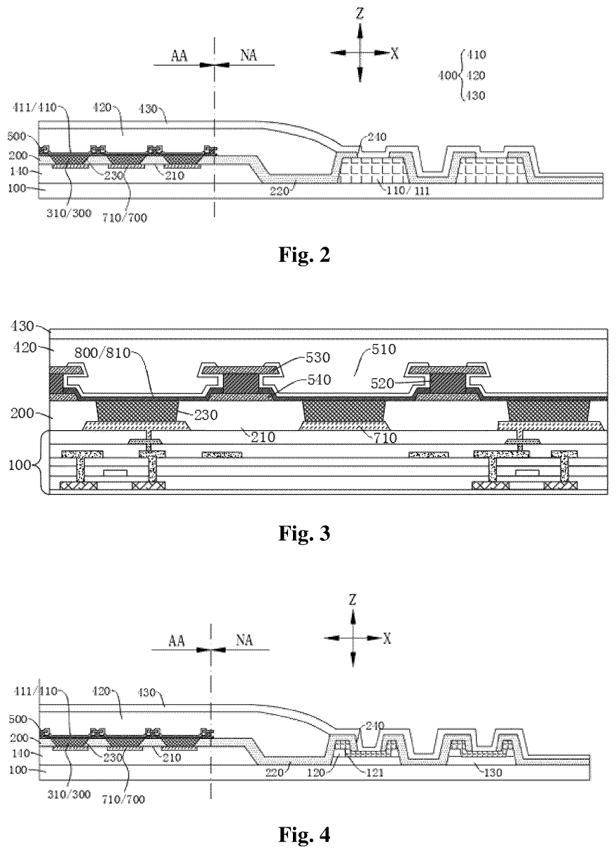

Referring to FIG. 1 to FIG. 3, FIG. 1 is a schematic structural view of a display panel according to an embodiment of the present application; FIG. 2 is a cross-sectional view at A-A in FIG. 1; FIG. 3 is a partial enlarged schematic structural view of FIG. 2.

As shown in FIG. 1 to FIG. 3, embodiments of a first aspect of the present application provide a display panel including a display region AA and a non-display region NA surrounding at least a part of the display region AA, the display panel includes a base plate 100, a pixel definition layer 200 provided on the base plate 100, a light-emitting layer 300, and an encapsulation layer 400. The pixel definition layer 200 includes a pixel definition portion 210 located in the display region AA and a definition portion 220 located in the non-display region NA, and the pixel definition portion 210 is provided with a plurality of pixel openings 230; the light-emitting layer 300 includes light-emitting units 310 each located in the pixel opening 230; and the encapsulation layer 400 is located on a side of the light-emitting layer 300 away from the base plate 100, the encapsulation layer 400 includes a first encapsulation layer 410 and a second encapsulation layer 420 located on a side of the first encapsulation layer 410 away from the light-emitting layer 300, the first encapsulation layer 410 is located in the display region AA and encapsulates the light-emitting units 310, and at least a part of the second encapsulation layer 420 extends to the non-display region NA and is connected to the definition portion 220.

In the display panel according to the embodiments of the present application, the display panel includes the base plate 100, the pixel definition layer 200, the light-emitting layer 300, and the encapsulation layer 400. The pixel definition layer 200 includes the pixel definition portion 210 located in the display region AA and the definition portion 220 located in the non-display region NA. The pixel definition portion 210 in the display region AA is provided with pixel openings 230, and the light-emitting unit 310 is provided within the pixel opening 230, so that the display region AA of the display panel can emit light and display. The encapsulation layer 400 includes the first encapsulation layer 410 and the second encapsulation layer 420, and the encapsulation portion 411 of the first encapsulation layer 410 is configured to encapsulate the light-emitting units 310, so as to reduce the impact of water and oxygen intrusion on the light-emitting effect of the light-emitting units 310. The second encapsulation layer 420 in the non-display region NA is connected to the definition portion 220 of the pixel definition layer 200. That is, the definition portion 220 and the second encapsulation layer 420 extend out from the first encapsulation layer 410 and are connected to each other outside the first encapsulation layer 410, which can reduce the problem that the encapsulation performance of the second encapsulation layer 420 is affected by the excessive fluidity of the second encapsulation layer 420 caused by the contact area between the first encapsulation layer 410 and the second encapsulation layer 420 being too large. Accordingly, the embodiments of the present application can improve the encapsulation performance of the encapsulation layer 400, thereby improving the overall process performance of the display panel.

The base plate 100 may be provided in various manners, and the base plate 100 may include a substrate, as well as a first conductive layer, a second conductive layer and a third conductive layer which are provided on a side of the substrate and are stacked. An insulation layer is provided between adjacent conductive layers. Exemplarily, a pixel driving circuit is provided within the base plate 100 and includes a transistor and a storage capacitor. The transistor includes a semiconductor, a gate, a source, and a drain. The storage capacitor includes a first electrode plate and a second electrode plate. As an example, the gate and the first electrode plate may be located in the first conductive layer, the second electrode plate may be located in the second conductive layer, and the source and the drain may be located in the third conductive layer.

Optionally, the base plate 100 is provided with a first electrode layer 700 including a plurality of first electrodes 710 which are provided at intervals, and an orthographic projection of each of the first electrodes 710 on the base plate 100 at least partially overlaps an orthographic projection of a corresponding pixel opening 230 on the base plate 100, so that each of the first electrodes 710 can drive a corresponding light-emitting unit 310 located in the pixel opening 230 to emit light.

The non-display region NA is provided in various manners, for example, the non-display region NA is a light transmission aperture region and is configured to transmit ambient light, so that the photosensitive element can acquire ambient light information. Or, the non-display region NA is a frame region of the display panel. The size of the frame region is relatively great, the length of the encapsulation layer 400 along the edge of the frame region is greater, and the definition portion 220 and the second encapsulation layer 420 are connected to each other in the frame region, so that the encapsulation performance of the encapsulation layer 400 can be further improved.

A material of the pixel definition layer 200 is provided in various manners, and the material of the pixel definition layer 200 may include an organic material.

Or, in some other optional embodiments, the material of the pixel definition layer 200 may further include an inorganic material, so that the pixel definition layer 200 has a good compactness. That is, the material of the definition portion 220 includes the inorganic material, so that the definition portion 220 has a good compactness.

Optionally, the material of the pixel definition layer 200 includes silicon nitride (SiNx), silicon oxide (SiOx), and silicon oxynitride (SiON).

Optionally, the pixel definition layer 200 is a single film layer, or the pixel definition layer 200 includes a plurality of stacked film layers, that is, the pixel definition layer 200 may be formed by stacking a plurality of film layers.

Optionally, the film-forming condition of the pixel definition layer 200 is above 150° C., and thus films formed in the film-forming condition of the pixel definition layer 200 are more compactness than films formed in the film-forming condition of the first encapsulation layer 410. Therefore, free bonds of O are relatively less, so that the overflow of the second encapsulation layer 420 is buffered to a certain extent.

Optionally, a material of the first encapsulation layer 410 includes an inorganic material, that is, a material of each of the encapsulation portions 411 includes an inorganic material, so that each of the encapsulation portions 411 has a good compactness, and is able to provide a better compactness protection for a corresponding light-emitting unit 310.

Optionally, a material of the second encapsulation layer 420 includes an organic material, so that the second encapsulation layer 420 may have a relatively great thickness, and the flatness of the whole surface of the encapsulation layer 400 can be adjusted.

In some optional embodiments, the encapsulation layer 400 further includes a third encapsulation layer 430 located on a side of the second encapsulation layer 420 away from the base plate 100, and a part of the third encapsulation layer 430 in the non-display region NA extends out from the second encapsulation layer 420 and is connected to the definition portion 220.

In these optional embodiments, the encapsulation layer 400 further includes the third encapsulation layer 430, and the third encapsulation layer 430 in the non-display region NA extends out from the second encapsulation layer 420. That is, the size of the third encapsulation layer 430 is greater than the size of the second encapsulation layer 420, and the third encapsulation layer 430 is connected to the definition portion 220 outside the second encapsulation layer 420, thereby improving the overall sealing performance of the encapsulation layer 400.

Optionally, an edge of an orthographic projection of the second encapsulation layer 420 on the base plate 100 is located on a side of an outer edge of an orthographic projection of the definition portion 220 on the base plate 100 facing the display region AA. That is, the edge of the definition portion 220 extends out from the second encapsulation layer 420 along a direction from the display region AA to the non-display region NA, and the definition portion 220 may be hermetically connected to the third encapsulation layer 430 outside the second encapsulation layer 420. That is, one part of the definition portion 220 is connected to the second encapsulation layer 420, and the other part of the definition portion 220 is connected to the third encapsulation layer 430, so that the contact area between the definition portion 220 and the second encapsulation layer 420 and the third encapsulation layer 430 can be increased, and the sealing effect of the encapsulation layer 400 can be further improved.

Optionally, the orthographic projection of the second encapsulation layer 420 on the base plate 100 is located within an orthographic projection of the third encapsulation layer 430 on the base plate 100. That is, the size of the third encapsulation layer 430 is greater than the size of the second encapsulation layer 420, and the third encapsulation layer 430 can provide a longer sealing length, so that the sealing effect of the encapsulation layer 400 can be further improved.

Optionally, a material of the third encapsulation layer 430 includes an inorganic material, so that the third encapsulation layer 430 has a better sealing effect, thereby improving the overall sealing performance of the encapsulation layer 400.

In some optional embodiments, the non-display region NA is provided with a dam 110, the dam 110 is provided on the base plate 100 and located on a side of the pixel definition layer 200 facing the base plate 100, the second encapsulation layer 420 is located on a side of the dam 110 facing the display region AA, and the definition portion 220 and the third encapsulation layer 430 extend to a side of the dam 110 away from the display region AA.

In these optional embodiments, the second encapsulation layer 420 is located on a side of the dam 110 facing the display region AA, the second encapsulation layer 420 is limited by the dam 110 in the region where the dam 110 is enclosed and formed, and the third encapsulation layer 430 and the definition portion 220 extend to a side of the dam 110 away from the display region AA. That is, the third encapsulation layer 430 and the definition portion 220 extend to the outside of the dam 110, so that the encapsulation length can be lengthened and the encapsulation yield can be improved.

Optionally, the definition portion 220 and the third encapsulation layer 430 are connected on the dam 110, that is, the definition portion 220 and the third encapsulation layer 430 are connected on a side of the dam 110 away from the base plate 100, and the dam 110 is typically relatively high, so that the dam 110 can provide a relatively high stage difference. The definition portion 220 and the third encapsulation layer 430 are connected at a position with a relatively high stage height, so that the encapsulation yield can be further improved.

In some optional embodiments, the dam 110 includes an organic layer 111 connected to the definition portion 220, the definition portion 220 is provided with a first hole 240, and an orthographic projection of the first hole 240 on the base plate 100 is located within an orthographic projection of the organic layer 111 on the base plate 100.

In these optional embodiments, the organic layer 111 within the dam 110 is directly connected to the definition portion 220, and the organic layer 111 may generate gas during the manufacturing process. The definition portion 220 is provided with the first hole 240, and the orthographic projection of the first hole 240 on the base plate 100 is located within the orthographic projection of the organic layer 111 on the base plate 100. That is, at least a part of the organic layer 111 can be exposed by the first hole 240, so that the gas generated in the organic layer 111 can be released through the first hole 240, thereby reducing the phenomenon of film layer peeling caused by the gas remaining between the organic layer 111 and the definition portion 220, and further improving the encapsulation effect of the encapsulation layer 400.

Optionally, the base plate 100 is provided with a planarization layer 140, and when the planarization layer 140 is manufactured, materials in a part of the dams 110 may be retained to form the organic layer 111, so that the height of the dam 110 is increased. That is, the organic layer 111 and the planarization layer 140 may be provided on the same layer and made of the same material, so as to simplify the manufacturing process of the display panel and increase the height of the dam 110.

Optionally, the base plate 100 further includes a plurality of conductive layers, an insulation layer is provided between the plurality of conductive layers, and when the insulation layer is manufactured, the materials in a part of the dams 110 may be retained to form the organic layer 111, that is, the insulation layer and the organic layer 111 are provided on the same layer and made of the same material.

Optionally, a material of the organic layer 111 includes an organic material. The organic layer 111 may have a relatively great thickness to ensure that the dam 110 has a relatively great height.

One or more first holes 240 may be provided, and a plurality of first holes 240 may be provided at intervals along an extension direction of the dam 110. By providing the plurality of first holes 240, gas at different positions within the organic layer 111 may be released, and the problem of film layer peeling occurring easily between the organic layer 111 and the definition portion 220 is further reduced.

Optionally, one dam 110 may be provided, and the one dam 110 may be in a closed ring shape around the display region AA.

Optionally, two or more dams 110 may be provided, and the two or more dams 110 are nested with each other. Each of the dams 110 is correspondingly provided with the first hole 240, that is, the organic layer 111 of each of the dams 110 is correspondingly provided with the first hole 240, so that the problem of film layer peeling occurring easily between the organic layer 111 and the definition portion 220 is further reduced.

In some optional embodiments, as shown in FIG. 4, the base plate 100 is further provided with a signal line 120, at least a part of the signal line 120 is located on a side of the organic layer 111 facing the base plate 100, the signal line 120 is provided with a second hole 121, and the orthographic projection of the first hole 240 on the base plate 100 is located within an orthographic projection of the second hole 121 on the base plate 100.

In these optional embodiments, the signal line 120 is provided with the second hole 121, and the orthographic projection of the first hole 240 on the base plate 100 is located within the orthographic projection of the second hole 121 on the base plate 100, that is, the size of the first hole 240 is less than the size of the second hole 121, and a part of the definition portion 220 extends into the second hole 121 to wrap an inner wall surface of the signal line 120 facing the second hole 121, so as to provide protection for the signal line 120.

Optionally, the signal line 120 may intersect the dam 110 along the direction from the display region AA to the non-display region NA, or the signal line 120 may be provided in parallel with a part of the dam 110.

Optionally, the signal line 120 may be a power signal line 120. For example, the signal line 120 is configured to transmit a low-level voltage signal, or the signal line 120 is configured to transmit a driving power voltage signal.

Optionally, the signal line 120 may be provided as a single film layer, or the signal line 120 may include a plurality of stacked conductive layers. For example, the signal line 120 includes a first sub-layer and a second sub-layer that are stacked, the second sub-layer is located on a side of the first sub-layer away from the base plate 100, a material of the first sub-layer may be aluminium, and a material of the second sub-layer may be titanium. Optionally, the signal line 120 may further include a third sub-layer located on a side of the first sub-layer away from the second sub-layer, and a material of the third sub-layer may include titanium.

Optionally, a pad layer 130 is provided on a side of the signal line 120 facing the base plate 100, and a material of the pad layer 130 may include an organic material. In the manufacturing process, the thickness of the organic layer 111 on the signal line 120 tends to be thin due to the fluidity of the organic material during the coating and patterning process. During the process of etching the definition portion 220 including the inorganic material, the etching gas contains an elemental oxygen gas, and the elemental oxygen gas may etch away the relatively thin organic layer 111, resulting in the second sub-layer. The etching gas etching the definition portion 220 containing the inorganic material may contain elemental fluorine gas, and the elemental fluorine gas may react with titanium to damage the second sub-layer, possibly resulting in exposure of the first sub-layer. Under a condition that the material of the first sub-layer includes aluminum, the aluminum may react with the oxygen element to form a greater volume of aluminum oxide, thereby causing separation of the film layers and resulting in encapsulation degradation.

In the embodiments of the present application, a region where the signal line 120 exists is covered by the definition portion 220, so that the probability that the signal line 120 is deformed by etching or reacts with the oxygen element can be reduced, thereby further improving the encapsulation yield.

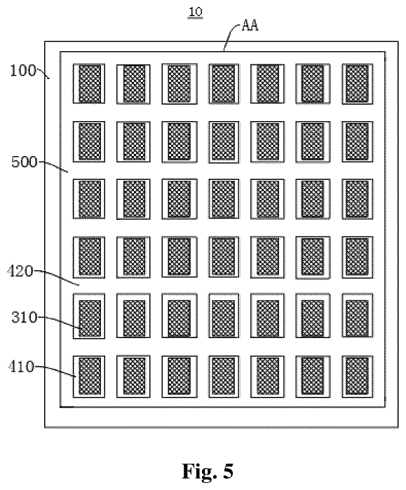

In some optional embodiments, as shown in FIG. 5, the display panel further includes an isolation structure 500 provided on the base plate 100, the isolation structure 500 encloses and forms isolation openings 510, and an orthographic projection of the isolation opening 510 on the base plate 100 at least partially overlaps an orthographic projection of the pixel opening 230 on the base plate 100. The orthographic projection of the isolation opening 510 on the base plate 100 is located within the orthographic projection of the pixel opening 230 on the base plate 100. The first encapsulation layer 410 includes a plurality of encapsulation portions 411, and each of the encapsulation portions 411 is configured to encapsulate a light-emitting unit 310 located in a corresponding isolation opening 510.

In these optional embodiments, by providing the isolation structure 500, the light-emitting material can be divided into a plurality of light-emitting units 310 which are independent from each other and each located in a corresponding isolation opening 510, so that an evaporation process for the fine mask can be omitted and the manufacturing process of the display panel can be simplified. The orthographic projection of the isolation opening 510 on the base plate 100 at least partially overlaps the orthographic projection of the pixel opening 230 on the base plate 100, so that the light-emitting unit 310 can be located within both the isolation opening 510 and the pixel opening 230. Each of the encapsulation portions 411 is configured to encapsulate the light-emitting unit 310 located in the corresponding isolation opening 510, so that the encapsulation performance of each of the light-emitting unit 310 is improved.

Optionally, the orthographic projection of the pixel opening 230 on the base plate 100 is located within the orthographic projection of the isolation opening 510 on the base plate 100, that is, the size of the isolation opening 510 is greater than the size of the pixel opening 230, so that more light-emitting material can fall into the pixel opening 230.

Optionally, the display panel further includes a second electrode layer 800, the second electrode layer 800 includes second electrodes 810 respectively located at a side of the light-emitting units 310 away from the base plate 100, and the second electrode 810 and the first electrode 710 may interact with each other to drive the light-emitting unit 310 to emit light. Optionally, a material of the isolation structure 500 includes a conductive material, and the second electrodes 810 are connected to the isolation structure 500, so that the second electrodes 810 may be interconnected as an entire electrode by the isolation structure 500.

Optionally, each of the encapsulation portions 411 is located on a side of a corresponding second electrode 810 away from the base plate 100, so that each of the encapsulation portions 411 can provide protection for the corresponding second electrode 810.

Optionally, an orthographic projection of each of the second electrodes 810 on the base plate 100 is located within an orthographic projection of a corresponding encapsulation portion 411 on the base plate 100, that is, the size of the encapsulation portion 411 is greater than the size of the second electrode 810, so that the encapsulation portion 411 can provide better protection for the second electrode 810.

Optionally, an orthographic projection of each of the isolation openings 510 on the base plate 100 is located within the orthographic projection of a corresponding encapsulation portion 411 on the base plate 100, that is, the size of the encapsulation portion 411 is relatively great, and the encapsulation portion 411 may extend to a surface of the isolation structure 500 away from the base plate 100 to provide better encapsulation performance.

Optionally, a gap is provided between adjacent encapsulation portions 411 and is located on a side of the isolation structure 500 away from the base plate 100, that is, a plurality of encapsulation portions 411 are independent from each other.

The isolation structure 500 may be provided in various manners, for example, the isolation structure 500 is a single-layer structure and includes a first surface facing the base plate 100 and a second surface away from the base plate 100, and an orthographic projection of the first surface on the base plate 100 is located within an orthographic projection of the second surface on the base plate 100. That is, the size of the first surface is less than the size of the second surface, so that a concave structure may be formed under the second surface, and when the light-emitting unit 310 is manufactured subsequently, the light-emitting material is partitioned into a plurality of independent light-emitting units 310 on an edge of the second surface.

Optionally, in other embodiments, the isolation structure 500 includes a first layer 520 and a second layer 530 which are stacked, the second layer 530 is located on a side of the first layer 520 away from the base plate 100, and an orthographic projection of the first layer 520 on the base plate 100 is located within an orthographic projection of the second layer 530 on the base plate 100. That is, the size of the first layer 520 is less than the size of the second layer 530, so that a concave structure may be formed under the second layer 530, and when the light-emitting unit 310 is manufactured subsequently, the light-emitting material is partitioned into a plurality of independent light-emitting units 310 on an edge of the second layer 530.

Optionally, a material of the first layer 520 includes a conductive material and is connected to the second electrodes 810, so that a plurality of the second electrodes 810 may be interconnected as an entire electrode by the first layer 520.

Optionally, a material of the second layer 530 includes a conductive material, and the material of the second layer 530 is different from the material of the first layer 520. In these optional embodiments, the material of the second layer 530 includes the conductive material, so that that the distribution area of the conductive structure can be increased, and the overall resistance of the second electrodes 810 can be decreased. The material of the second layer 530 is different from the material of the first layer 520, so that the first layer 520 and the second layer 530 with different sizes are formed using different etching rates when different materials react with the same etching solution.

Optionally, the isolation structure 500 further includes a third layer 540 located on a side of the first layer 520 facing the base plate 100, the orthographic projection of the first layer 520 on the base plate 100 is located within an orthographic projection of the third layer 540 on the base plate 100. Under a condition that the isolation structure 500 is formed by performing a side etching on the first layer 520, the third layer 540 may have a protection effect to reduce the impact of etching on a film layer on a side of the third layer 540 facing the base plate 100.

The embodiments of the first aspect of the present application further provide a display panel including a display region AA and a non-display region NA surrounding at least a part of the display region AA, and the display panel includes: a base plate 100; a light-emitting layer 300 including a plurality of light-emitting units 310; and an encapsulation layer 400 located on a side of the light-emitting layer 300 away from the base plate 100, wherein the encapsulation layer 400 includes a first encapsulation layer 410 and a second encapsulation layer 420 located on a side of the first encapsulation layer 410 away from the light-emitting layer 300, the first encapsulation layer 410 is located in the display region AA and includes a plurality of encapsulation portions 411 respectively covering the plurality of light-emitting units 310, and the second encapsulation layer 420 covers the plurality of encapsulation portions 411.

In the display panel according to the embodiments of the present application, the display panel includes the base plate 100, the light-emitting layer 300, and the encapsulation layer 400. The encapsulation layer 400 includes the first encapsulation layer 410 and the second encapsulation layer 420, and the encapsulation portion 411 of the first encapsulation layer 410 is configured to encapsulate the light-emitting units 310, so as to reduce the impact of water and oxygen intrusion on the light-emitting effect of the light-emitting units 310. The size of the second encapsulation layer 420 is relatively great, so that the plurality of encapsulation portions 411 are covered, and the encapsulation performance of the encapsulation layer 400 can be improved.

Optionally, the base plate 100, the pixel definition layer 200, the light-emitting layer 300, the encapsulation layer 400, and the dam 110 are provided as described above, which will not be repeated herein.

For example, orthographic projections of the plurality of encapsulation portions 411 on the base plate 100 are located within an orthographic projection of the second encapsulation layer 420 on the base plate 100, and the size of the second encapsulation layer 420 is relatively great, so that the plurality of encapsulation portions 411 are covered, and the encapsulation performance of the encapsulation layer 400 can be improved. Optionally, the second encapsulation layer 420 may extend from the display region AA to the non-display region NA to increase the coverage of the second encapsulation layer 420.

Optionally, the display panel 10 includes a dam 110 located in the non-display region NA, the second encapsulation layer 420 is located on a side of the dam 110 facing the display region, and the second encapsulation layer 420 can be limited in the dam 110 by the dam 110. Optionally, at least a part of the second encapsulation layer 420 extends from the display region AA to a side of the dam 110 away from the display region AA, and the second encapsulation layer 420 may overflow to a side of the dam 110 away from the display region AA.

In some optional embodiments, the display panel 10 further includes a pixel definition layer 200 provided on the base plate 100, the pixel definition layer 200 includes a pixel definition portion 210 located in the display region AA and a definition portion 220 located in the non-display region NA, the pixel definition portion 210 is provided with a plurality of pixel openings 230, the light-emitting unit 310 is located in the pixel opening 230, and the definition portion 220 and the second encapsulation layer 420 are connected on a side of the dam 110 facing the display region AA.

In these embodiments, first encapsulation layers 410 and the dams 110 are provided at intervals, a gap is provided between the first encapsulation layer 410 and the dam 110, and the second encapsulation layer 420 and the definition portion 220 may be connected to each other in the gap, which can reduce the problem that the encapsulation performance of the second encapsulation layer 420 is affected by the excessive fluidity of the second encapsulation layer 420 caused by the contact area between the first encapsulation layer 410 and the second encapsulation layer 420 being too large.

Optionally, as described above, the dam 110 includes an organic layer 111 connected to the definition portion 220, the definition portion 220 is provided with a first hole 240, and an orthographic projection of the first hole 240 on the base plate 100 is located within an orthographic projection of the organic layer 111 on the base plate 100.

In these optional embodiments, the organic layer 111 within the dam 110 is directly connected to the definition portion 220, and the organic layer 111 may generate gas during the manufacturing process. The definition portion 220 is provided with the first hole 240, and the orthographic projection of the first hole 240 on the base plate 100 is located within the orthographic projection of the organic layer 111 on the base plate 100, that is, at least a part of the organic layer 111 can be exposed by the first hole 240, so that the gas generated in the organic layer 111 can be released through the first hole 240, thereby reducing the phenomenon of film layer peeling caused by the gas remaining between the organic layer 111 and the definition portion 220, and further improving the encapsulation effect of the encapsulation layer 400.

In some optional embodiments, the definition portion 220 extends to a side of the dam 110 away from the display region AA. The distribution area of the definition portion 220 can be increased, and the contact area between the definition portion 220 and the second encapsulation layer 420 can be increased.

In some optional embodiments, the encapsulation layer 400 further includes a third encapsulation layer 430 located on a side of the second encapsulation layer 420 away from the base plate 100, and a part of the third encapsulation layer 430 in the non-display region NA extends out from the second encapsulation layer 420 and is connected to the definition portion 220.

In these optional embodiments, the encapsulation layer 400 further includes the third encapsulation layer 430, and the third encapsulation layer 430 in the non-display region NA extends out from the second encapsulation layer 420, that is, the size of the third encapsulation layer 430 is greater than the size of the second encapsulation layer 420, and the third encapsulation layer 430 is connected to the definition portion 220 outside the second encapsulation layer 420, thereby improving the overall sealing performance of the encapsulation layer 400.

Optionally, the second encapsulation layer 420 is located on a side of the dam 110 facing the display region AA, and the definition portion 220 and the third encapsulation layer 430 are connected on the dam 110. That is, the definition portion 220 and the third encapsulation layer 430 are connected on a side of the dam 110 away from the base plate 100, and the dam 110 is typically relatively high, so that the dam 110 can provide a relatively high stage difference. The definition portion 220 and the third encapsulation layer 430 are connected at a position with a relatively high stage height, so that the encapsulation yield can be further improved.

Embodiments of the second aspect of the present application provide a display apparatus including the display panel according to any of the embodiments of the first aspect. Since the display apparatus according to the embodiments of the second aspect of the present application includes the display panel according to any of the embodiments of the first aspect, the display apparatus according to the embodiments of the second aspect of the present application has the beneficial effects of the display panel according to any of the embodiments of the first aspect, which is not repeated herein.

The display device according to the embodiments of the present application includes, but is not limited to a mobile phone, a personal digital assistant (PDA), a tablet computer, an e-book, a television, an access control, a smart fixed phone, a console and other devices with a display function.

Although the present application has been described with reference to the preferred embodiments, various modifications can be made thereto and components thereof can be replaced with their equivalents without departing from the scope of the present application. In particular, various technical features described in various embodiments can be combined in any manner as long as there is no structural conflict. The present application is not limited to the specific embodiments described herein, and includes all technical solutions that fall within the scope of the claims.

What is claimed is:

1. A display panel, comprising a display region and a non-display region surrounding at least a part of the display region, and the display panel comprising:
a base plate;
a pixel definition layer provided on the base plate, wherein the pixel definition layer comprises a pixel definition portion located in the display region and a definition portion located in the non-display region, and the pixel definition portion is provided with a plurality of pixel openings;
a light-emitting layer comprising light-emitting units each located in the pixel opening; and
an encapsulation layer located on a side of the light-emitting layer away from the base plate, wherein the encapsulation layer comprises a first encapsulation layer and a second encapsulation layer located on a side of the first encapsulation layer away from the light-emitting layer, the first encapsulation layer is located in the display region and encapsulates the light-emitting units, and at least a part of the second encapsulation layer extends to the non-display region and is connected to the definition portion.

2. The display panel according to claim 1, wherein a material of the pixel definition layer comprises an inorganic material;
a material of the second encapsulation layer comprises an organic material;
a material of the first encapsulation layer comprises an inorganic material;
the material of the pixel definition layer comprises at least one of silicon oxide, silicon nitride, silicon oxynitride; and
the pixel definition layer is a single film layer, or the pixel definition layer comprises a plurality of stacked film layers.

3. The display panel according to claim 1, wherein the encapsulation layer further comprises a third encapsulation layer located on a side of the second encapsulation layer away from the base plate, and a part of the third encapsulation layer in the non-display region extends out from the second encapsulation layer and is connected to the definition portion.

4. The display panel according to claim 3, wherein an edge of an orthographic projection of the second encapsulation layer on the base plate is located on a side of an outer edge of an orthographic projection of the definition portion on the base plate facing the display region;
the orthographic projection of the second encapsulation layer on the base plate is located within an orthographic projection of the third encapsulation layer on the base plate; and
a material of the third encapsulation layer comprises an inorganic material.

5. The display panel according to claim 3, wherein the non-display region is provided with a dam, the dam is provided on the base plate and located on a side of the pixel definition layer facing the base plate, the second encapsulation layer is located on a side of the dam facing the display region, and the definition portion and the third encapsulation layer extend to a side of the dam away from the display region; and
the definition portion and the third encapsulation layer are connected on a side of the dam away from the base plate.

6. The display panel according to claim 5, wherein the dam comprises an organic layer connected to the definition portion, the definition portion is provided with a first hole, and an orthographic projection of the first hole on the base plate is located within an orthographic projection of the organic layer on the base plate; and
a plurality of first holes are provided at intervals along an extension direction of the dam.

7. The display panel according to claim 6, wherein the base plate is further provided with a signal line, at least a part of the signal line is located on a side of the organic layer facing the base plate, the signal line is provided with a second hole, and the orthographic projection of the first hole on the base plate is located within an orthographic projection of the second hole on the base plate.

8. The display panel according to claim 7, wherein the signal line comprises a first sub-layer and a second sub-layer located on a side of the first sub-layer away from the base plate, a material of the first sub-layer comprises aluminium, and a material of the second sub-layer comprises titanium; and
the signal line further comprises a third sub-layer located on a side of the first sub-layer away from the second sub-layer, and a material of the third sub-layer comprises titanium.

9. The display panel according to claim 7, wherein the base plate is further provided with a pad layer located on a side of the signal line facing the base plate, and a material of the pad layer comprises an organic material.

10. The display panel according to claim 1, wherein the display panel further comprises:
an isolation structure provided on the base plate, wherein the isolation structure encloses and forms isolation openings, an orthographic projection of the isolation opening on the base plate at least partially overlaps an orthographic projection of the pixel opening on the base plate;
the orthographic projection of the isolation opening on the base plate is located within the orthographic projection of the pixel opening on the base plate;
the first encapsulation layer comprises a plurality of encapsulation portions, and each of the encapsulation portions encapsulates the light-emitting unit located in a corresponding isolation opening.

11. The display panel according to claim 10, wherein the display panel further comprises a second electrode layer, the second electrode layer comprises second electrodes respectively located at a side of the light-emitting units away from the base plate, and the second electrode is electrically connected to the isolation structure;
an orthographic projection of each of the isolation openings on the base plate is located within an orthographic projection of a corresponding encapsulation portion on the base plate; and
a gap is provided between adjacent encapsulation portions and is located on a side of the isolation structure away from the base plate.

12. The display panel according to claim 10, wherein the isolation structure comprises a first layer and a second layer located on a side of the first layer away from the base plate, an orthographic projection of the first layer on the base plate is located within an orthographic projection of the second layer on the base plate; and
a material of the first layer comprises a conductive material.

13. The display panel according to claim 12, wherein the isolation structure further comprises a third layer located on a side of the first layer facing the base plate, and the orthographic projection of the first layer on the base plate is located within an orthographic projection of the third layer on the base plate.

14. The display panel according to claim 1, wherein the non-display region is a frame region of the display panel.

15. A display panel, comprising a display region and a non-display region surrounding at least a part of the display region, and the display panel comprising:
a base plate;
a light-emitting layer comprising a plurality of light-emitting units; and
an encapsulation layer located on a side of the light-emitting layer away from the base plate, wherein the encapsulation layer comprises a first encapsulation layer and a second encapsulation layer located on a side of the first encapsulation layer away from the light-emitting layer, the first encapsulation layer is located in the display region and comprises a plurality of encapsulation portions respectively covering the plurality of light-emitting units, and the second encapsulation layer covers the plurality of encapsulation portions.

16. The display panel according to claim 15, wherein orthographic projections of the plurality of encapsulation portions on the base plate are located within an orthographic projection of the second encapsulation layer on the base plate; and
the second encapsulation layer extends from the display region to the non-display region.

17. The display panel according to claim 16, wherein the display panel comprises a dam located in the non-display region, and the second encapsulation layer is located on a side of the dam facing the display region, or at least a part of the second encapsulation layer extends from the display region to a side of the dam away from the display region.

18. The display panel according to claim 17, wherein the display panel further comprises a pixel definition layer provided on the base plate, the pixel definition layer comprises a pixel definition portion located in the display region and a definition portion located in the non-display region, the pixel definition portion is provided with a plurality of pixel openings, the light-emitting unit is located in the pixel opening, and the definition portion and the second encapsulation layer are connected on a side of the dam facing the display region;
the definition portion extends to a side of the dam away from the display region;
the dam comprises an organic layer connected to the definition portion, the definition portion is provided with a first hole, and an orthographic projection of the first hole on the base plate is located within an orthographic projection of the organic layer on the base plate.

19. The display panel according to claim 18, wherein the encapsulation layer further comprises a third encapsulation layer located on a side of the second encapsulation layer away from the base plate, a part of the third encapsulation layer in the non-display region extends out from the second encapsulation layer and is connected to the definition portion; and
the second encapsulation layer is located on a side of the dam facing the display region, and the definition portion and the third encapsulation layer are connected on the dam.

20. A display apparatus, comprising the display panel according to claim 1.
